(19) United States
(12) Patent Application Publication
(10) Pub. No.: US 2023/0422505 A1
(43) Pub. Date: Dec. 28, 2023

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventors: Ryota FUJITSUKA, Yokkaichi (JP); Takanori YAMANAKA, Yokkaichi (JP); Hiroki KISHI, Yokkaichi (JP)

(73) Assignee: Kioxia Corporation, Tokyo (JP)

(21) Appl. No.: 18/332,792

(22) Filed: Jun. 12, 2023

(30) Foreign Application Priority Data
Jun. 22, 2022 (JP) 2022-100043

(51) Int. Cl. H10B 43/27

(52) U.S. Cl. CPC H10B 43/27

(57) ABSTRACT

A semiconductor memory device includes: a stack having an insulating layer and a conductive layer, each layer being stacked alternately in a first direction; a semiconductor layer through the insulating and the conductive layer; a memory layer between the stack and the semiconductor layer in a second direction; and an insulation extending from the insulating layer toward the semiconductor layer in the second direction. The insulation and the memory layer define an interface therebetween in a cross-section, the interface having a first point and a second point, the first point overlapping with a middle portion of the insulating layer, the second point overlapping with an end portion of the insulating layer. The second point is closer to the insulating layer in the second direction than the first point is. The interface curves from the first point to the second point to protrude toward the semiconductor layer.

### CROSS-REFERENCE TO RELATED APPLICATIONS

This application is based upon and claims the benefit of priority from Japanese Patent Application No. 2022-100043, filed on Jun. 22, 2022; the entire contents of which are incorporated herein by reference.

### FIELD

Embodiments relate to a semiconductor memory device and a method of manufacturing a semiconductor memory device.

### BACKGROUND

A known semiconductor memory device has bit lines, word lines, and memory cells connected to the bit lines and word lines. The semiconductor memory device can select a bit line and a word line and apply a voltage to write and read data to/from a memory cell.

### BRIEF DESCRIPTION OF THE DRAWINGS

FIG. 1 is a block diagram illustrating a configuration embodiment of a memory.

FIG. 2 is a circuit diagram illustrating the circuit configuration of a memory cell array 100.

FIG. 3 is an explanatory schematic cross-sectional view of an example of the structure of a NAND string NS.

FIG. 4 is a schematic cross-sectional view taken along the line A-B in FIG. 3.

FIG. 5 is an explanatory schematic cross-sectional view of an example of a method of forming the example of the NAND string NS illustrated in FIG. 3 and FIG. 4.

FIG. 6 is an explanatory schematic cross-sectional view of the example of the method of forming the example of the NAND string NS illustrated in FIG. 3 and FIG. 4.

FIG. 7 is an explanatory schematic cross-sectional view of the example of the method of forming the example of the NAND string NS illustrated in FIG. 3 and FIG. 4.

FIG. 8 is an explanatory schematic cross-sectional view of the example of the method of forming the example of the NAND string NS illustrated in FIG. 3 and FIG. 4.

FIG. 9 is an explanatory schematic cross-sectional view of the example of the method of forming the example of the NAND string NS illustrated in FIG. 3 and FIG. 4.

FIG. 10 is an explanatory schematic cross-sectional view of the example of the method of forming the example of the NAND string NS illustrated in FIG. 3 and FIG. 4.

FIG. 11 is an explanatory schematic cross-sectional view of another example of the structure of the NAND string NS.

FIG. 12 is an explanatory schematic cross-sectional view of the other example of the structure of the NAND string NS.

FIG. 13 is an explanatory schematic cross-sectional view of an example of a method of forming the other example of the NAND string NS illustrated in FIG. 11 and FIG. 12.

FIG. 14 is an explanatory schematic cross-sectional view of the example of the method of forming the other example of the NAND string NS illustrated in FIG. 11 and FIG. 12.

FIG. 15 is an explanatory schematic cross-sectional view of the example of the method of forming the other example of the NAND string NS illustrated in FIG. 11 and FIG. 12.

FIG. 16 is an explanatory schematic cross-sectional view of the example of the method of forming the other example of the NAND string NS illustrated in FIG. 11 and FIG. 12.

FIG. 17 is an explanatory schematic cross-sectional view of a first structure example of a NAND string NS of an embodiment.

FIG. 18 is a schematic cross-sectional view taken along the line A-B in FIG. 17.

FIG. 19 is an enlarged view illustrating part of FIG. 17.

FIG. 20 is an explanatory schematic cross-sectional view of an example of a method of forming the first structure example of the NAND string NS.

FIG. 21 is an explanatory schematic cross-sectional view of the example of the method of forming the first structure example of the NAND string NS.

FIG. 22 is an explanatory schematic cross-sectional view of the example of the method of forming the first structure example of the NAND string NS.

FIG. 23 is an explanatory schematic cross-sectional view of the example of the method of forming the first structure example of the NAND string NS.

FIG. 24 is an explanatory schematic cross-sectional view of the example of the method of forming the first structure example of the NAND string NS.

FIG. 25 is an explanatory schematic cross-sectional view of the example of the method of forming the first structure example of the NAND string NS.

FIG. 26 is an explanatory schematic cross-sectional view of the example of the method of forming the first structure example of the NAND string NS.

FIG. 27 is an explanatory schematic cross-sectional view of the example of the method of forming the first structure example of the NAND string NS.

FIG. 28 is an explanatory schematic cross-sectional view of the example of the method of forming the first structure example of the NAND string NS.

FIG. 29 is an explanatory schematic cross-sectional view of the example of the method of forming the first structure example of the NAND string NS.

FIG. 30 is an explanatory schematic cross-sectional view of a second structure example of the NAND string NS of the embodiment.

FIG. 31 is a schematic cross-sectional view taken along the line A-B in FIG. 30.

FIG. 32 is an enlarged view illustrating part of FIG. 30.

FIG. 33 is an explanatory schematic cross-sectional view of an example of a method of forming the second structure example of the NAND string NS.

FIG. 34 is an explanatory schematic cross-sectional view of the example of the method of forming the second structure example of the NAND string NS.

FIG. 35 is an explanatory schematic cross-sectional view of the example of the method of forming the second structure example of the NAND string NS.

FIG. 36 is an explanatory schematic cross-sectional view of the example of the method of forming the second structure example of the NAND string NS.

### DETAILED DESCRIPTION

A semiconductor memory device of an embodiment includes: a stack having an insulating layer and a conductive layer, the insulating layer and the conductive layer being stacked alternately in a first direction; a semiconductor layer provided through the insulating layer and the conductive layer; a memory layer provided between the stack and the semiconductor layer in a second direction intersecting with the first direction; and an insulation extending from the insulating layer toward the semiconductor layer in the second direction. The insulation and the memory layer define an interface therebetween in a cross-section along the first direction, the cross-section including the stack, the semiconductor layer, the memory layer and the insulation, the interface having a first point and a second point, the first point overlapping with a middle portion in the first direction of the insulating layer, the second point overlapping with an end portion in the first direction of the insulating layer. The second point is closer to the insulating layer in the second direction than the first point is. The interface curves from the first point to the second point to protrude toward the semiconductor layer.

An embodiment will be hereinafter described with reference to the drawings. The relation of the thickness and planar dimension of constituent elements illustrated in the drawings, a thickness ratio among the constituent elements, and so on may be different from actual ones. Further, in the embodiment, substantially the same constituent elements are denoted by the same reference signs and a description thereof will be omitted when appropriate.

In this specification, “connecting” includes not only physically connecting but also electrically connecting unless specified.

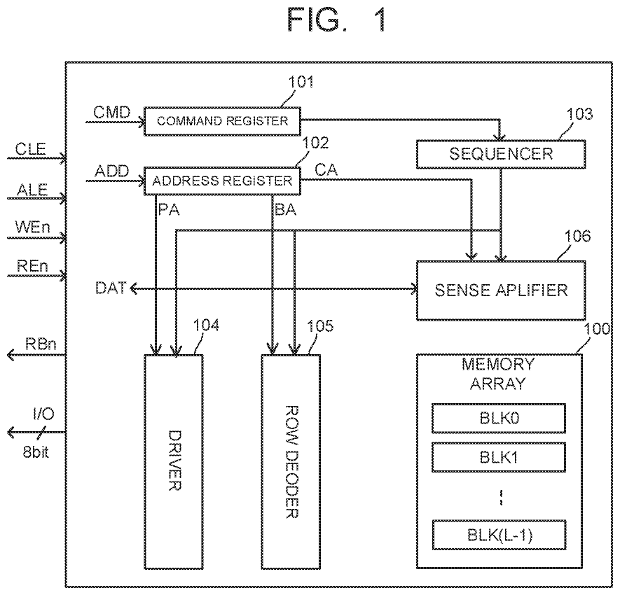

A configuration example of a semiconductor memory device will be described. FIG. 1 is a block diagram illustrating a configuration example of a memory. The memory includes a memory cell array 100, a command register 101, an address register 102, a sequencer 103, a driver 104, a row decoder 105, and a sense amplifier 106.

The memory cell array 100 includes a plurality of blocks BLK (BLK0 to BLK(L−1) (L is a natural number equal to or more than two)). The blocks BLK are each an assembly of a plurality of memory cells that store data.

The command register 101 retains a command signal CMD received from a memory controller. The command signal CMD includes command data that causes the sequencer 103 to execute a read operation, a write operation, or an erase operation, for instance.

The address register 102 retains an address signal ADD received from the memory controller. The address signal ADD contains a block address BA, a page address PA, and a column address CA, for instance. For example, the block address BA, the page address PA, and the column address CA are used for the selection of a block BLK, a word line WL, and a bit line BL respectively.

The sequencer 103 controls the operation of the memory. For example, based on the command signal CMD retained in the command register 101, the sequencer 103 controls the driver 104, the row decoder 105, the sense amplifier 106, and so on to execute an operation such as a read operation, a write operation, and an erase operation.

The driver 104 generates a voltage for use in the read operation, the write operation, the erase operation, and so on. The driver 104 includes, for example, a DA converter. Then, for example, based on the page address PA retained in the address register 102, the driver 104 applies the generated voltage to a signal line corresponding to the selected word line WL.

Based on the block address BA retained in the address register 102, the row decoder 105 selects a corresponding one of the blocks BLK in the memory cell array 100. Then, the row decoder 105 transfers the voltage applied to the signal line corresponding to the selected word line WL to the selected word line WL in the selected block BLK, for instance.

In the write operation, the sense amplifier 106 applies a desired voltage to each bit line BL according to write data DAT received from the memory controller. In the read operation, based on the voltage of the bit line BL, the sense amplifier 106 determines data stored in the memory cell and transfers the determination result as read data DAT to the memory controller.

The communication between the memory and the memory controller supports a NAND interface standard, for instance. For example, the communication between the memory and the memory controller uses a command latch enable signal CLE, an address latch enable signal ALE, a write enable signal WEn, a read enable signal REn, a ready/busy signal RBn, and an input/output signal I/O.

The command latch enable signal CLE indicates that an input/output signal I/O received by the memory is a command signal CMD. The address latch enable signal ALE indicates that the received signal I/O is an address signal ADD. The write enable signal WEn is a signal instructing the memory to receive the input/output signal I/O. The read enable signal REn is a signal instructing the memory to output an input/output signal I/O.

The ready/busy signal RBn is a signal notifying the memory controller whether the memory is in a ready state in which it accepts a command from the memory controller or in a busy state in which it does not accept the command.

The input/output signal I/O is a signal with, for example, an eight-bit width and can include signals such as a command signal CMD, an address signal ADD, and a write data signal DAT.

The memory and the memory controller described above may be combined to constitute one semiconductor memory device. Examples of such a semiconductor memory device include a memory card such as an SD card and a solid state drive (SSD).

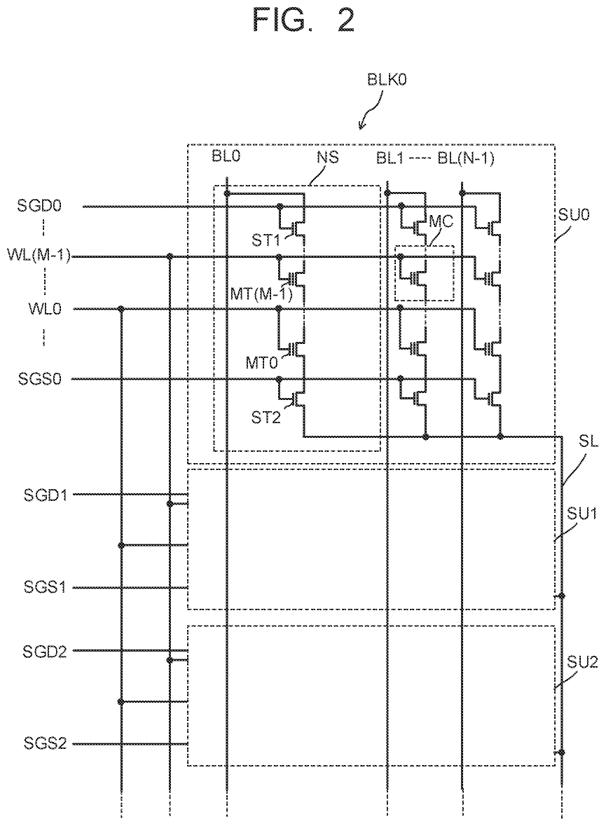

Next, a circuit configuration example of the memory cell array 100 will be described. FIG. 2 is a circuit diagram illustrating the circuit configuration of the memory cell array 100. FIG. 2 illustrates the block BLKO as an example, and the other blocks BLK also have the same configuration.

The block BLK includes a plurality of string units SU. The string units SU each include a plurality of NAND strings NS. It should be noted that the number of the string units SU is not limited though FIG. 2 illustrates three string units SU (SU0 to SU2).

The NAND strings NS are each connected to one of the plurality of bit lines BL (BL0 to BL(N−1) (N is a natural number equal to or more than two)). The NAND strings NS each include, for example, memory transistors MT, a select transistor ST1, and a select transistor ST2. The memory transistors MT each constitute the single memory cell MC. The NAND strings NS each have the plurality of memory cells connected in series. The memory including such memory cells is also called a chain-type memory.

The memory transistors MT each include a control gate and a charge storage layer and are capable of nonvolatile data retention. The memory transistors MT may be of a MONOS type using an insulating film as the charge storage layer or may be an FG type using a conductive layer as the charge storage layer. Hereinafter, in the embodiment, the MONOS type will be taken as an example in the description.

The control gates of the memory transistors MT are each connected to corresponding one of the word lines WL. One of a source and a drain of one of the plurality of memory transistors MT is connected to the other of a source and a drain of the other of the plurality of memory transistors MT. FIG. 2 illustrates the plurality of memory transistors MT (MT0 to MT(M−1) (M is a natural number equal to or more than two)), but the number of the memory transistors MT is not limited.

The select transistor ST1 is used for the selection of a string unit SU in various operations. The number of the select transistors ST1 is not limited.

The select transistor ST2 is used for the selection of a string unit SU in various operations. The number of the select transistors ST2 is not limited.

In each of the NAND strings NS, a drain of the select transistor ST1 is connected to corresponding one of the bit lines BL. A source of the select transistor ST1 is connected to one end of the memory transistor MT connected thereto in series. The other end of the memory transistor MT connected in series is connected to a drain of the select transistor ST2.

In the same block BLK, sources of the select transistors ST2 are connected to a source line SL. Gates of the select transistors ST1 of the string units SU are connected respectively to corresponding selection gate lines SGD. Gates of the memory transistors MT are connected respectively to corresponding word lines WL. Gates of the select transistors ST2 are connected respectively to corresponding selection gate lines SGS.

The NAND strings NS assigned the same column address CA in the plurality of blocks BL are connected to the same bit line BL. The source lines SL are connected between the plurality of blocks BLK.

Next, structure examples of the NAND string NS will be described.

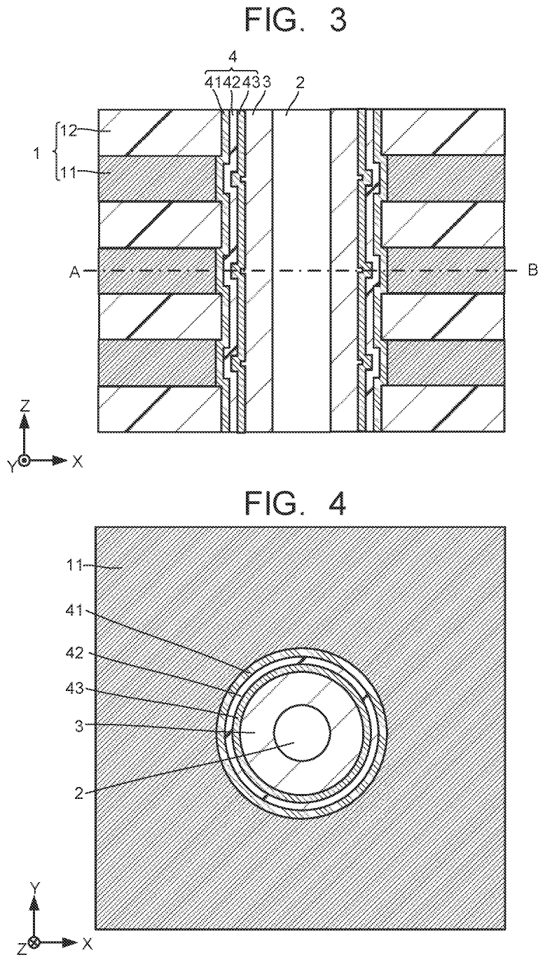

FIG. 3 is an explanatory schematic cross-sectional view of an example of the structure of the NAND string NS for comparison with a NAND string NS of the embodiment. It indicates an X-axis, a Y-axis orthogonal to the X-axis, and a Z-axis orthogonal to the X-axis and the Y-axis and illustrates part of an X-Z cross-section including the X-axis and the Z-axis. FIG. 4 is a schematic cross-sectional view taken along the line A-B in FIG. 3 and illustrates part of an X-Y cross-section including the X-axis and the Y-axis.

The NAND string NS illustrated in FIG. 3 and FIG. 4 includes stacks 1, an insulator 2, a semiconductor layer 3, and a memory layer 4.

The stacks 1 each include conductive layers 11 and insulating layers 12. Each conductive layer 11 and each insulating layer 12 are alternately stacked along the Z-axis direction. The conductive layers 11 constitute the word lines WL and gate electrodes of the memory transistors MT and extend along the X-axis direction. The insulator 2 extends along the direction in which the conductive layers 11 and the insulating layers 12 are stacked (Z-axis direction), for instance.

The semiconductor layer 3 penetrates through the stacks 1 along the Z-axis direction. The semiconductor layer 3 forms a channel region of the memory transistors MT. The semiconductor layer 3 is electrically connected to the bit line BL and the source line SL.

The memory layer 4 is provided on the opposite side of on the semiconductor layer 3 from the insulator 2. The memory layer 4 is provided between the conductive layers 11 and the semiconductor layer 3 in the X-axis direction or the Y-axis direction.

The memory layer 4 has a block insulation film 41, a charge storage film 42, and a tunnel insulation film 43.

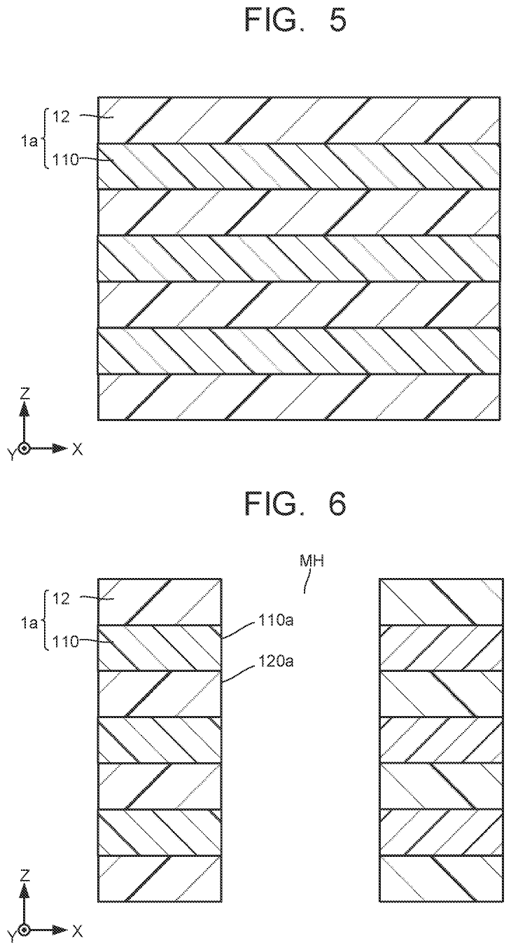

Next, an example of a method of forming the example of the NAND string NS illustrated in FIG. 3 and FIG. 4 in a method of manufacturing the semiconductor memory device will be described with reference to FIG. 5 to FIG. 10. FIG. 5 to FIG. 10 are explanatory schematic cross-sectional views of the example of the method of forming the example of the NAND string NS illustrated in FIG. 3 and FIG. 4 and illustrate part of the X-Z cross-section.

First, as illustrated in FIG. 5, each insulating layer 110 and each insulating layer 12 are alternately stacked along the Z-axis direction to form stacks 1a. The insulating layers 110 are sacrificial layers. The sacrificial layers are layers where to form spaces later.

Next, as illustrated in FIG. 6, the stacks 1a are processed, whereby an opening (a memory hole MR) penetrating through the stacks 1a along the Z-axis direction, surfaces 110a, and surfaces 120a are formed.

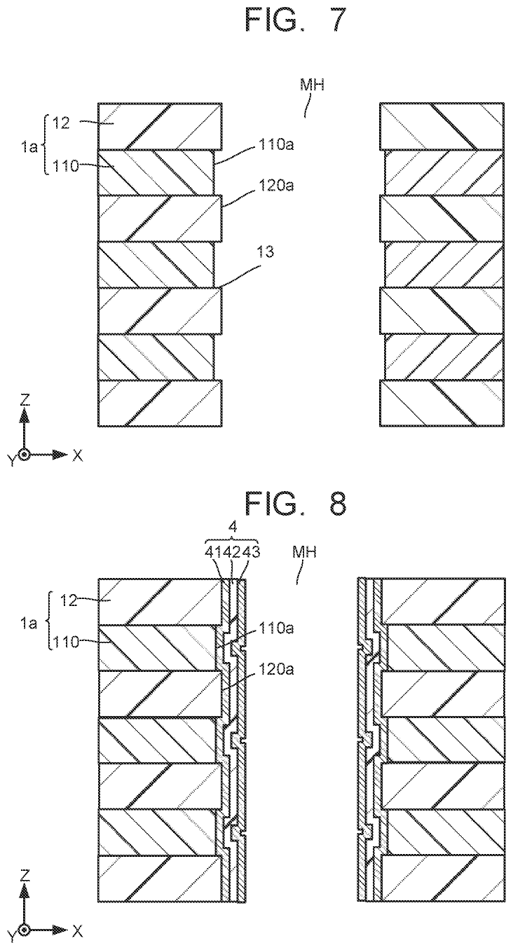

Next, as illustrated in FIG. 7, the insulating layers 110 are partly removed (recessed) along the X-Y cross-section, whereby inner grooves 13 are formed in the stacks 1a.

Next, as illustrated in FIG. 8, the block insulation film 41 is formed on the surfaces 110a and the surfaces 120a, the charge storage film 42 is formed on the surface of the block insulation film 41, and the tunnel insulation film 43 is formed on the surface of the charge storage film 42.

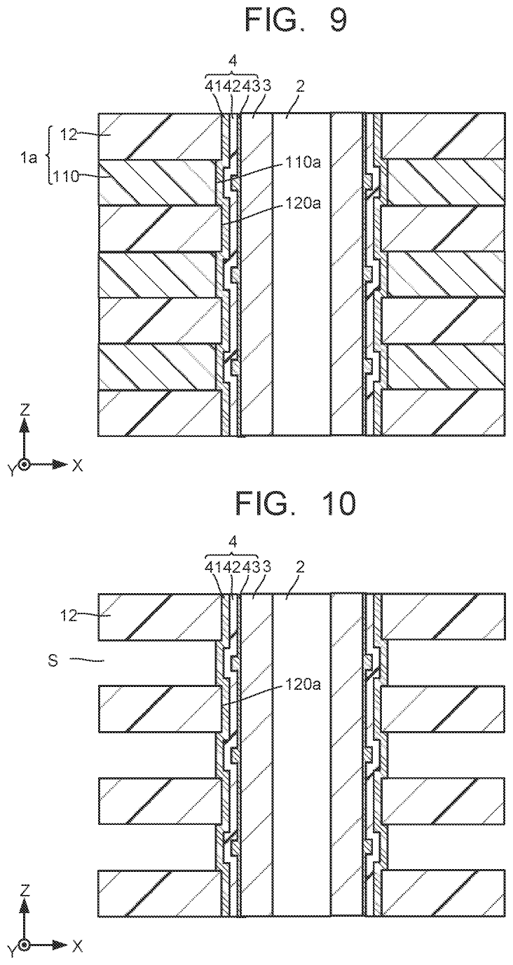

Next, as illustrated in FIG. 9, the semiconductor layer 3 is formed on the surface of the tunnel insulation film 43, and the insulator 2 is formed on the surface of the semiconductor layer 3.

Next, as illustrated in FIG. 10, the insulating layers 110 are removed, whereby the spaces S are formed, and thereafter the conductive layers 11 are formed in the spaces S. Through the above process, the example of the NAND string NS illustrated in FIG. 3 and FIG. 4 can be formed.

In the NAND string NS illustrated in FIG. 3 and FIG. 4, since the conductive layers 11 are more apart from the semiconductor layer 3 than the insulating layers 12 in the X-axis direction or the Y-axis direction, it is possible to reduce electrical interference between the adjacent memory cells MC. To form such a structure, the insulating layers 110 which are sacrificial layers between the insulating layers 12 are recessed using wet etching. Accordingly, it is difficult for the conductive layers 11 to have a large volume. A small volume of the conductive layers 11 results in a large electrical resistance of the word lines WL. Further, the use of the wet etching to recess the sacrificial layers leads to poor embeddability of the conductive layers 11, which may cause the blocking insulating film 41 to be damaged by a deposition gas.

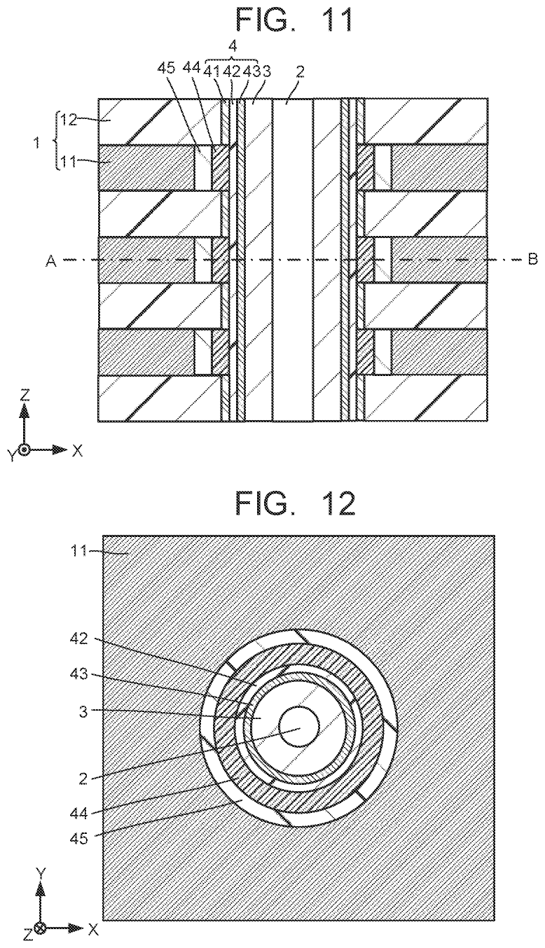

FIG. 11 is an explanatory schematic cross-sectional view of another example of the structure of the NAND string NS, and it indicates an X-axis, a Y-axis orthogonal to the X-axis, and a Z-axis orthogonal to the X-axis and the Y-axis and illustrates part of an X-Z cross-section including the X-axis and the Z-axis. FIG. 12 is an explanatory schematic cross-sectional view of the other example of the structure of the NAND string NA and illustrates part of an X-Y cross-section including the X-axis and the Y-axis.

The NAND string NS illustrated in FIG. 11 and FIG. 12 includes stacks 1, an insulator 2, a semiconductor layer 3, a memory layer 4, insulating layers 44, and insulating layers 45. For the description of the stacks 1, the insulator 2, the semiconductor layer 3, and the memory layer 4, the description of the stacks 1, the insulator 2, the semiconductor layer 3, and the memory layer 4 illustrated in FIG. 3 and FIG. 4 can be referred to as required.

Each insulating layer 44 are provided between the corresponding conductive layer 11 and a charge storage film 42. The insulating layers 44 are provided in contact with the charge storage film 42. The insulating layers 44 function as charge storage films. The insulating layers 44 contain silicon nitride, for instance.

The insulating layers 45 are provided between the conductive layers 11 and the insulating layers 44. The insulating layers 45 contain silicon oxide, for instance. The insulating layers 45 function as block insulation films.

Next, an example of a method of forming the other example of the NAND string NS illustrated in FIG. 11 and FIG. 12 in the method of forming the semiconductor memory device will be described with reference to FIG. 13 to FIG. 16. FIG. 13 to FIG. 16 are explanatory schematic cross-sectional views of the example of the method of forming the other example of the NAND string NS illustrated in FIG. 11 and FIG. 12 and illustrate part of the X-Z cross-section.

First, as illustrated in FIG. 13, each insulating layer 110 and each insulating layer 12 are alternately stacked along the Z-axis direction to form stacks 1a, and the stacks 1a are processed, whereby a memory hole MH penetrating through the stacks 1a along the Z-axis direction, surfaces 110a, surfaces 120a are formed.

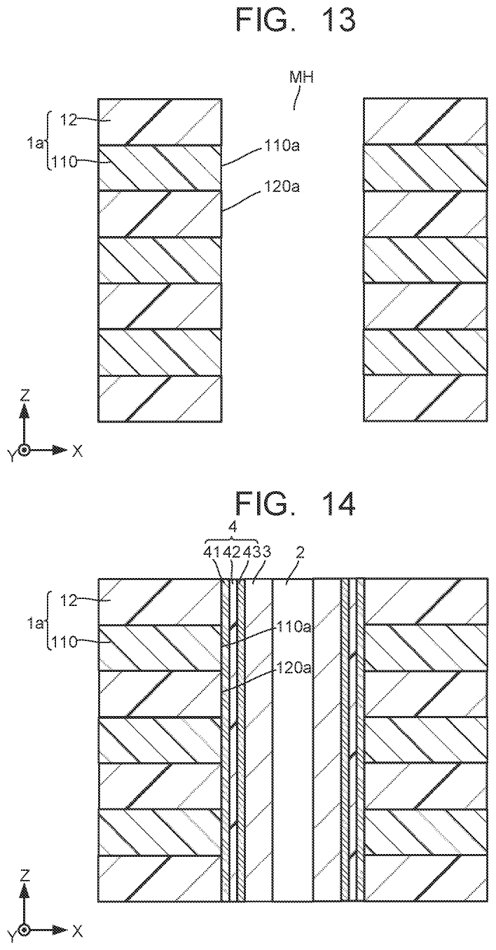

Next, as illustrated in FIG. 14, a block insulation film 41 is formed on the surfaces 110a and the surfaces 120a, the charge storage film 42 is formed on the surface of the block insulation film 41, a tunnel insulation film 43 is formed on the surface of the charge storage film 42, the semiconductor layer 3 is formed on the surface of the tunnel insulation film 43, and the insulator 2 is formed on the surface of the semiconductor layer 3.

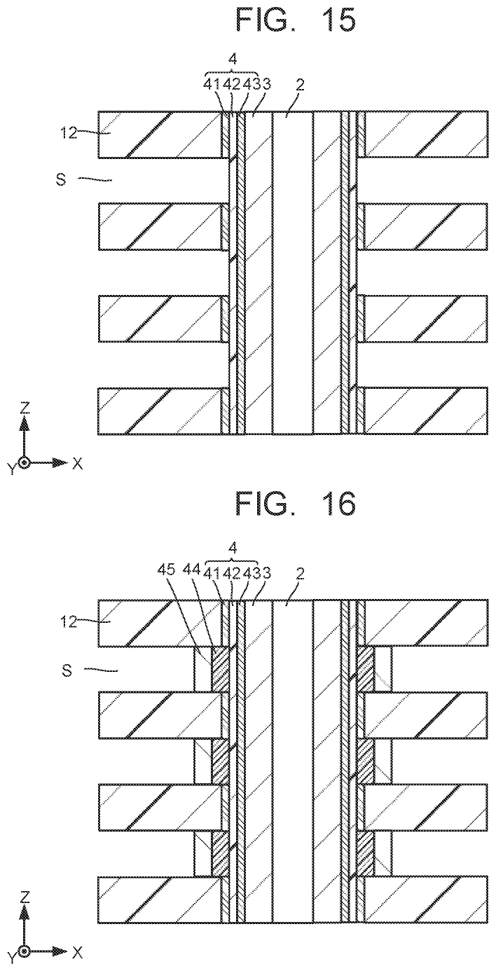

Next, as illustrated in FIG. 15, the insulating layers 110 are removed, whereby spaces S are formed, and regions, of the block insulation film 41, facing the insulating layers 110 are removed, whereby the charge storage film 42 is partly exposed.

Next, as illustrated in FIG. 16, using a selective growth method, the exposed parts of the charge storage film 42 are grown to form the insulating layers 44, and the insulating layers 45 are formed on the surfaces of the insulating layers 44. Thereafter, the conductive layers 11 are formed in the spaces S. Through the above process, the other example of the NAND string NS illustrated in FIG. 11 and FIG. 12 can be formed.

In the NAND string NS illustrated in FIG. 11 and FIG. 12, since the conductive layers 11 are more apart from the semiconductor layer 3 than the insulating layers 12 in the X-axis direction or the Y-axis direction, it is possible to reduce electrical interference between the adjacent memory cells MC. To form such a structure, the spaces are formed by the removal of the sacrificial layers, and after the parts, of the block insulation film 41, facing the spaces S are removed, the insulating layers 44 and the insulating layers 45 are formed in the spaces S, and thereafter, the conductive layers 11 are formed in the spaces S. Accordingly, it is difficult for the conductive layers 11 to have a large volume. A small volume of the conductive layers 11 results in a large electrical resistance of the word lines WL. Further, because of the need for making the memory hole MH smaller by an amount corresponding to the insulating layers 44 and the insulating layer 45, an aspect ratio of the memory hole MH becomes high, which makes the processing difficult. Further, the use of the selective growth method to form the insulating layers 44 causes the insulating layers 44 to have a poor film quality and a low function as the charge storage films, and thus results in a small shift amount of a threshold voltage of the memory cells MC (a narrow memory window), for instance.

On the other hand, the NAND string NS of the embodiment has a first structure example or a second structure example to be described below, for instance. These structure examples will be described below.

### First Structure Example of NAND String NS

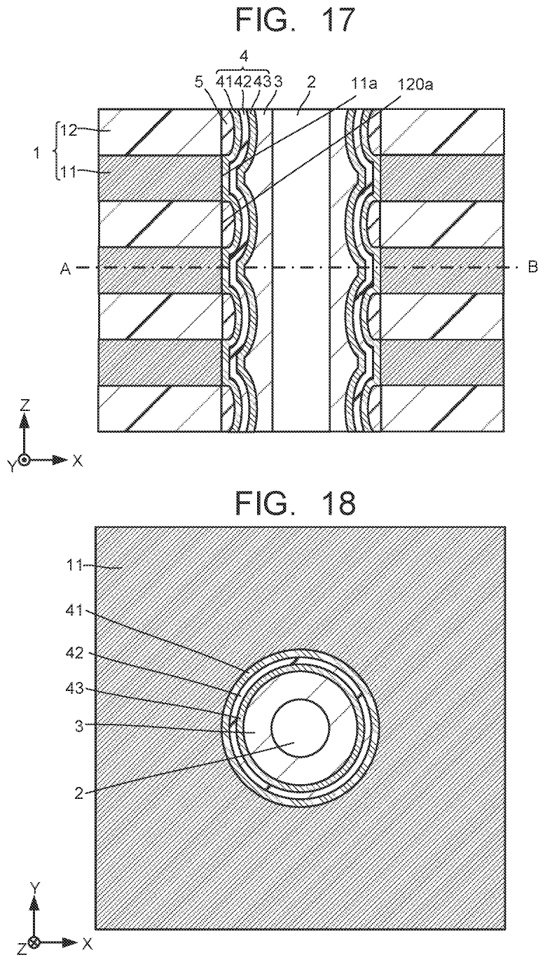

FIG. 17 is an explanatory schematic cross-sectional view of the first structure example of the NAND string NS of the embodiment, and it indicates an X-axis, a Y-axis orthogonal to the X-axis, and a Z-axis orthogonal to the X-axis and the Y-axis and illustrates part of an X-Z cross-section including the X-axis and the Z-axis. FIG. 18 is a schematic cross-sectional view taken along the line A-B in FIG. 17 and illustrates part of an X-Y cross-section including the X-axis and the Y-axis.

As illustrated in FIG. 17 and FIG. 18, the NAND string NS includes stacks 1, an insulator 2, a semiconductor layer 3, a memory layer 4, and insulations 5.

The stacks 1 each include a conductive layer 11 and an insulating layer 12. Each conductive layer 11 and each insulating layer 12 are alternately stacked along the Z-axis direction. Each conductive layer 11 constitute a word line WL and a gate electrode of a memory transistor MT and extend along the X-axis direction or the Y-axis direction. Examples of the conductive layers 11 include conductive layers such as tungsten layers. Examples of the insulating layers 12 include silicon oxide layers. Surfaces 11a, of the conductive layers 11, facing the memory layer 4 and surfaces 120a, of the insulating layers 12, facing the insulations 5 may be coplanar in the Z-axis direction. The conductive layers 11 each may have a stacked structure of a plurality of layers. The stacked structure may have, for example, a tungsten layer, a titanium nitride layer, and an aluminum oxide layer.

The insulator 2 is provided along the direction in which the conductive layers 11 and the insulating layers 12 are stacked (Z-axis direction), for instance. The insulator 2 functions as a core insulator. The insulator 2 has a pillar shape, for instance. Examples of the insulator 2 include a silicon oxide layer. The NAND string NS does not necessarily have to have the insulator 2.

As illustrated in FIG. 18, in the A-B cross-section, the semiconductor layer 3 surrounds the insulator 2. The semiconductor layer 3 penetrates through the stacks 1 along the Z-axis direction. The semiconductor layer 3 contains polysilicon, for instance. The semiconductor layer 3 forms channel regions of the memory transistors MT. The semiconductor layer 3 is electrically connected to the bit line BL and the source line SL. The outer periphery of the semiconductor layer 3 is covered with the memory layer 4.

The memory layer 4 is provided on the semiconductor layer 3 on the opposite side of the insulator 2. The memory layer 4 is provided between the conductive layers 11 and the semiconductor layer 3 and between the insulating layers 12 and the semiconductor layer 3 in the X-axis direction or the Y-axis direction. As illustrated in FIG. 18, in the A-B cross-section, the memory layer 4 surrounds the semiconductor layer 3.

The memory layer 4 has a block insulation film 41, a charge storage film 42, and a tunnel insulation film 43. The block insulation film 41 is provided between the insulations 5 and the semiconductor layer 3 in the X-axis direction or the Y-axis direction and contains, for example, oxygen and silicon. The block insulation film 41 is provided and extends between each conductive layer 11 and the semiconductor film 3 and between each insulating layer 12 and the semiconductor film 3. In this case, the block insulation film 41 is in contact with each of the insulations 5. The charge storage film 42 is provided between the tunnel insulation film 43 and the block insulation film 41 in the X-axis direction or the Y-axis direction and contains, for example, nitrogen and silicon. The tunnel insulation film 43 is provided between the charge storage film 42 and the semiconductor layer 3 and contains, for example, oxygen, nitrogen, and silicon.

The insulations 5 extend in the X-axis direction or the Y-axis direction from the insulating layers 12 toward the semiconductor layer 3. The insulations 5 are provided on the surfaces 120a. The insulations 5 are provided between the insulating layers 12 and the memory layer 4. Each insulation 5 surrounds the semiconductor layer 3. Each insulation 5 contains, for example, silicon and oxygen. In the case where each insulation 5 contains the same materials as those of the insulating layers 12, the interface between the insulation 5 and the insulating layer 12 may not be clearly visually recognized even using a device such as, for example, a transmission electron microscope (TEM). In this case, a portion overlapping with a line connecting surfaces facing the block insulation film 41, of the conductive layers 11 above and under the insulating layer 12 may be regarded as the interface between the insulation 5 and the insulating layer 12. The insulation 5 may be not in contact with each of the conductive layers 11. The block insulation film 41 may be not in contact with each of the insulating layers 12. The block insulation film 41 may be in contact with each of the conductive layers 11.

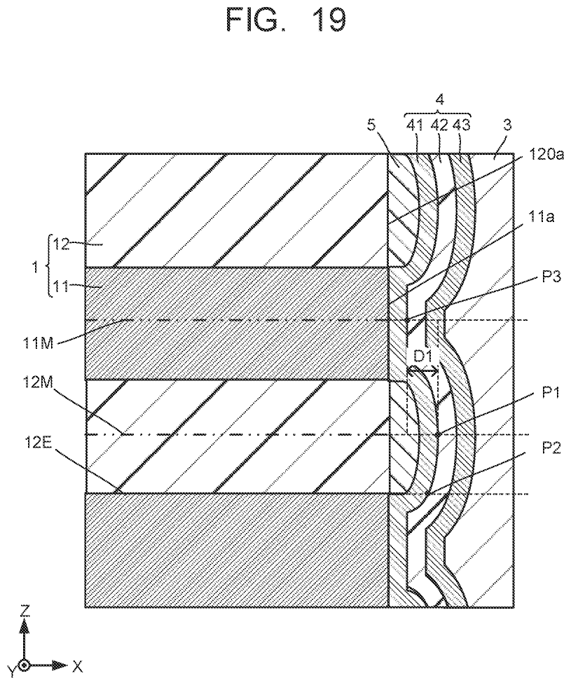

FIG. 19 is an enlarged view illustrating part of FIG. 17. The block insulation film 41 and the charge storage film 42 define an interface therebetween in a cross-section of the NAND string NS, the charge storage film 42 and the tunnel insulation film 43 define an interface therebetween in the cross-section, and the tunnel insulation film 43 and the semiconductor layer 3 define an interface therebetween in the cross-section, the cross-section including the conductive layers 11, the insulating layers 12, the semiconductor layer 3, the memory layer 4, and the insulations 5 and being taken along the Z-axis direction. Each of the three interfaces has a first point, a second point, and a third point, the first point overlapping with a middle portion 12M in Z-axis-direction of the insulating layers 12 in the X-axis direction or the Y-axis direction, the second point overlapping with end portions 12E in the Z-axis-direction of the insulating layer 12 in the X-axis direction or the Y-axis direction, and the third point overlapping with a middle portion 11M in the Z-axis-direction of the conductive layer 11. The middle portion 11M is a region whose depth from the upper surface or the lower surface of the conductive layer 11 is half the thickness (Z-axis-direction length) of the conductive layer 11, for instance. The middle portion 12M is a region whose depth from the upper surface or the lower surface of the insulating layer 12 is half the thickness (Z-axis-direction length) of the insulating layer 12, for instance. The end portions 12E are regions in contact with end portions in the Z-axis direction of the conductive layers 11. The second points are provided on the upper side and the lower side of the first point respectively. FIG. 19 illustrates an example where the interface between the block insulation film 41 and the charge storage film 42 has points P1, points P2, and points P3, each point P1 overlapping with the middle portion 12M in the Z-axis-direction of the insulating layer 12, each point P2 overlapping with the end portions 12E in the Z-axis-direction of the insulating layer 12, and each point P3 overlapping with the middle portion 11M in the Z-axis-direction of the conductive layer 11.

In each interface, each second point is closer to the insulating layer 12 in the X-axis direction or the Y-axis direction than each first point is. Each interface has a round shape or an arch shape bulging toward the semiconductor layer 3. Each interface curves from each first point to the upper and lower second points to protrude or bulge toward the semiconductor layer 3. This reduces interference between the adjacent memory cells MC, for instance. For example, as illustrated in FIG. 19, the interface between the block insulation film 41 and the charge storage film 42, curves from the point P1 to the points P2 above and under the point P1 to bulge toward the semiconductor layer 3.

In each of the interfaces, a distance D1 in the X-axis direction or the Y-axis direction between the second point and the third point is preferably not less than 0.5 nm nor more than 5 nm. If it is less than 0.5 nm, it is difficult to reduce electrical interface between the adjacent memory cells MC. If it exceeds 5 nm, an electric field concentrates on the middle portions 11M when, for example, a voltage is applied to a gate electrode WL, which may lower write efficiency.

The thickness (X-axis-direction or Y-axis-direction length) of the insulations 5 is preferably not less than 0.5 nm nor more than 5 nm. This indicates that all the regions including parts where the thickness of the insulations 5 is smallest up to parts where the thickness is largest may have a thickness of not less than 0.5 nm nor more than 5 nm.

Each insulation 5 may further contains carbon. The concentration of the carbon in each insulation 5 is preferably not less than 1 at. % nor more than 20 at. %. If it exceeds 20%, the insulation property of the insulation 5 worsen, which may cause leakage between the word lines L or may lower withstand voltage. In the case where the insulation 5 contains carbon, the insulating layer 12 and the insulation 5 can be distinguished by, for example, a difference in the carbon concentration. The carbon concentration in the insulation 5 is preferably higher than the carbon concentration in the insulating layers 12. That is, regions where the carbon concentration is less than 1 at. % can be defined as the insulating layer 12 and a region where the carbon concentration is not less than 1 at. % nor more than 20 at. % can be defined as the insulation 5. Further, the silicon concentration in the insulation 5 may be lower than the silicon concentration in the insulating layer 12. The element concentrations of the plurality of layers including the insulations 5 and the insulating layers 12 can be measured in an observation section by, for example, element analysis such as energy dispersive X-ray spectroscopy using a transmission electron microscope (TEM-EDX).

Being lower in relative dielectric constant than silicon oxide, carbon-containing silicon oxide is capable of reducing the fringe capacitance of the memory cells and increasing a coupling ratio of the memory transistors MT, and thus is capable of increasing the trapped electron density of regions, of the charge storage film 42, overlapping with the conductive layers 11 in the X-axis direction or the Y-axis direction at the time of, for example, data write to reduce electrical interference between the adjacent memory cells MC.

Next, an example of a method of forming the first structure example of the NAND string NS in the method of manufacturing the semiconductor memory device will be described with reference to FIG. 20 to FIG. 29. FIG. 20 to FIG. 29 are explanatory schematic cross-sectional views of the example of the method of forming the first structure example of the NAND string NS and illustrate part of the X-Z cross-section.

First, as illustrated in FIG. 20, each of insulating layers 110 and each of the insulating layers 12 are alternately stacked along the Z-axis direction to form stacks 1a. The insulating layers 110 are sacrificial layers. The sacrificial layers are layers where to form spaces later. Examples of the insulating layers 110 include silicon nitride layers.

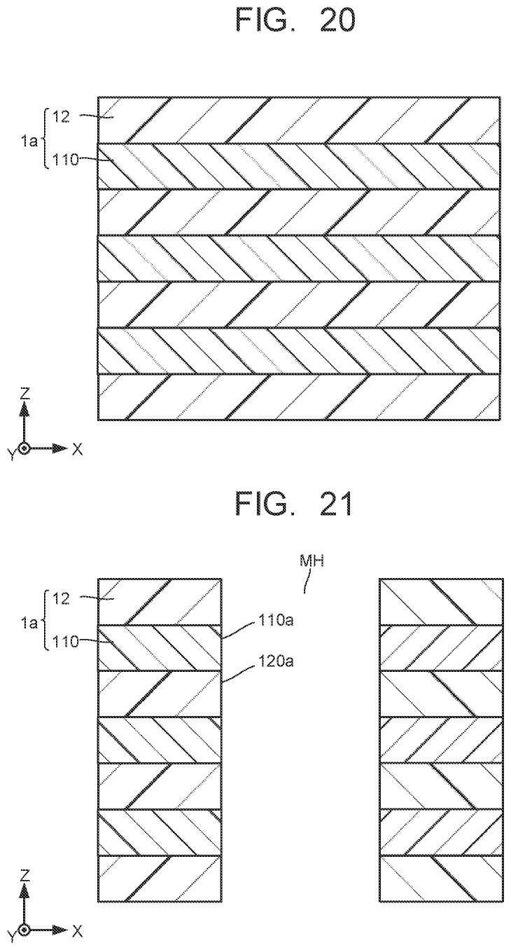

Next, as illustrated in FIG. 21, the stacks 1a are processed, whereby an opening (a memory hole MH) penetrating through the stacks 1a along the Z-axis direction, surfaces 110a, and surfaces 120a are formed. The surfaces 110a are provided on the insulating layers 110 and face the memory hole MH. The surfaces 120a are provided on the insulating layers 12 and face the memory hole MH. The stacks 1a can be processed using, for example, reactive ion etching (RIE).

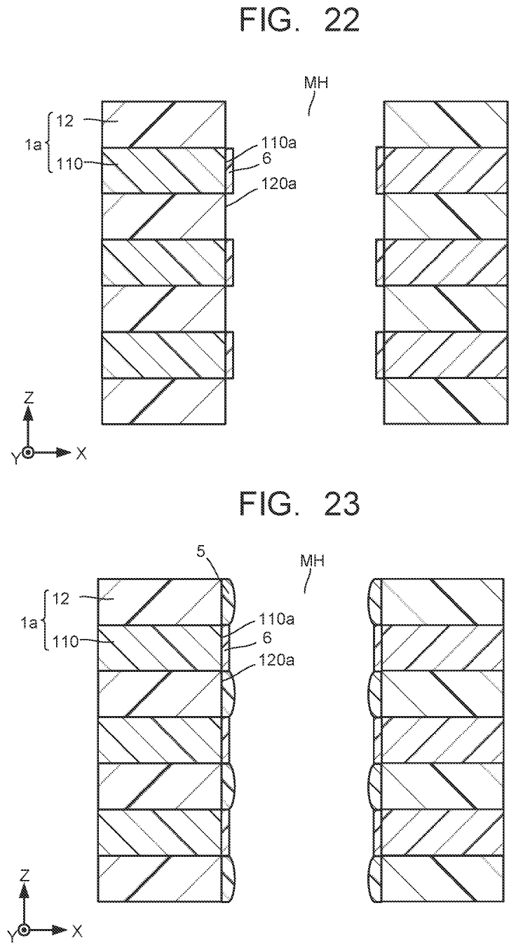

Next, as illustrated in FIG. 22, protective films 6 are formed on the surfaces 110a, and as illustrated in FIG. 23, the insulations 5 are formed on the surfaces 120a of the insulating layers 12. The insulations 5 can be formed using, for example, a selective growth method. The selective growth method is a technique in which, while part of a surface is covered with a protective film such as an insulating film, the film thickness or composition of the other part of the surface is changed. In the case where the insulations 5 containing, for example, carbon-containing silicon oxide is formed by the selective growth method, the surfaces 110a are modified using silicon chloride that can be adsorbed selectively only to NH groups present in the surfaces 110a of the insulating layers 110 which are, for example, silicon nitride films, whereby the protective films 6 are formed. Next, at a low temperature at which the protective films 6 do not detach from the surfaces 110a, the insulations 5 are formed using an aminosilane gas adsorbable selectively only to OH groups present in the surfaces 120a of the insulating layers 12 which are silicon oxide films and using an oxidant. The oxidant is preferably H₂O. A method of forming the insulations 5 is not limited to the above-described method. The insulations 5 can be formed using, for example, a chemical vapor deposition method (CVD) or an atomic layer deposition method (ALD). The protective films 6 can be formed using, for example, CVD or ALD but may be formed using a method such as coating.

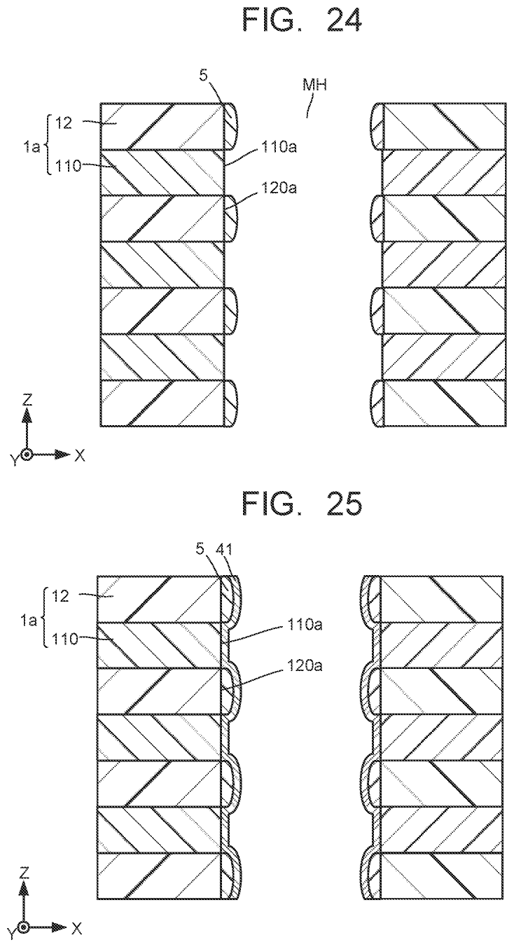

Next, as illustrated in FIG. 24, the protective films 6 are removed. The protective films 6 can be removed by, for example, etching such as dry etching or wet etching.

Next, as illustrated in FIG. 25, the block insulation film 41 is formed on the surfaces 110a and the surfaces of the insulations 5. The block insulation film 41 can be formed using, for example, CVD or ALD.

Next, as illustrated in FIG. 26, the charge storage film 42 is formed on the surface of the block insulation film 41. The charge storage film 42 can be formed using, for example, CVD or ALD.

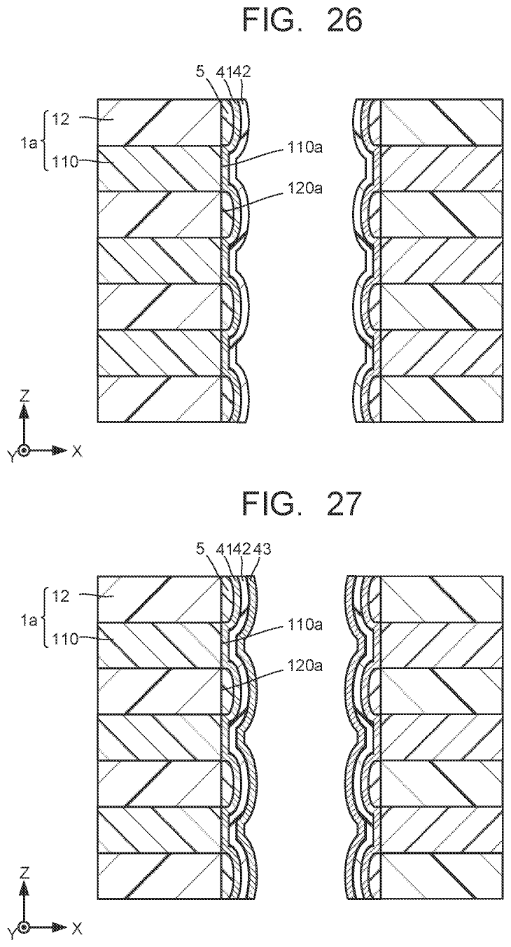

Next, as illustrated in FIG. 27, the tunnel insulation film 43 is formed on the surface of the charge storage film 42. The tunnel insulation film 43 can be formed using, for example, CVD or ALD.

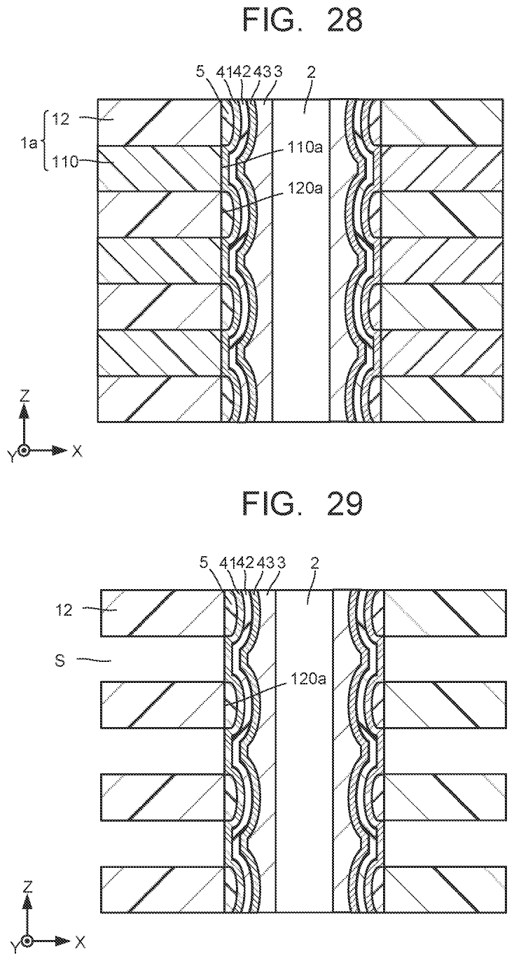

Next, as illustrated in FIG. 28, the semiconductor layer 3 is formed on the surface of the tunnel insulation film 43, and the insulator 2 is formed on the surface of the semiconductor layer 3. The semiconductor layer 3 and the insulator 2 can be formed using, for example, CVD or ALD.

Next, as illustrated in FIG. 29, the insulating layers 110 are removed, whereby the spaces S are formed, and thereafter, the conductive layers 11 are formed in the spaces S. The insulating layers 110 can be removed using, for example, wet etching or dry etching. The conductive layers 11 can be formed using, for example, CVD or ALD. Through the above process, it is possible to form the first structure example of the NAND string NS.

As described above, in the first structure example of the NAND string NS of the embodiment, the formation of the insulations 5 makes it possible to improve the trapped electron density of the regions, of the charge storage film 42, overlapping with the conductive layers 11 in the X-axis direction or the Y-axis direction to reduce electrical interference between the adjacent memory cells MC at the time of, for example, data write. Further, forming the insulations 5 in the shape curved to protrude toward the semiconductor layer 3 makes it possible to reduce field concentration near, for example, the end portions 12E. This can reduce operation failures of the memory cells MC.

### Second Structure Example of NAND String NS

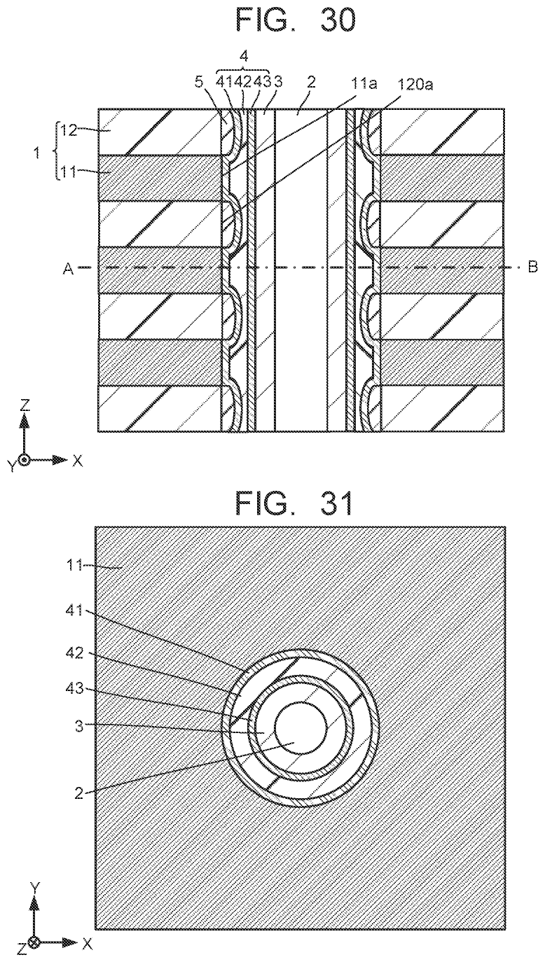

FIG. 30 is an explanatory schematic cross-sectional view of the second structure example of the NAND string NS of the embodiment, and it indicates an X-axis, a Y-axis orthogonal to the X-axis, and a Z-axis orthogonal to the X-axis and the Y-axis and illustrates part of an X-Z cross-section including the X-axis and the Z-axis. FIG. 31 is a schematic cross-sectional view taken along the line A-B in FIG. 30 and illustrates part of an X-Y cross-section including the X-axis and the Y-axis.

As illustrated in FIG. 30 and FIG. 31, the NAND string NS includes stacks 1, an insulator 2, a semiconductor layer 3, a memory layer 4, and insulations 5.

As illustrated in FIG. 31, in the A-B cross-section, the semiconductor layer 3 surrounds the insulator 2. The semiconductor layer 3 penetrates through the stacks 1 along the Z-axis direction. For the other description of the semiconductor layer 3, the description of the semiconductor layer 3 illustrated in FIG. 17 can be referred to as required.

The memory layer 4 is provided on the semiconductor layer 3 on the opposite side of the insulator 2. The memory layer 4 is provided between conductive layers 11 and the semiconductor layer 3 in the X-axis direction or the Y-axis direction.

The memory layer 4 has a block insulation film 41, a charge storage film 42, and a tunnel insulation film 43. The block insulation film 41 is provided between the insulations 5 and the semiconductor layer 3 in the X-axis direction or the Y-axis direction. The charge storage film 42 is provided between the tunnel insulation film 43 and the block insulation film 41 in the X-axis direction or the Y-axis direction. The tunnel insulation film 43 is provided between the charge storage film 42 and the semiconductor layer 3. For the other description of the block insulation film 41, the charge storage film 42, and the tunnel insulation film 43, the description of the block insulation film 41, the charge storage film 42, and the tunnel insulation film 43 illustrated in FIG. 17 can be referred to as required.

The insulations 5 extend in the X-axis direction or the Y-axis direction from the insulating layers 12 toward the semiconductor layer 3. The insulations 5 are provided on surfaces 120a. The insulations 5 are provided between the insulating layers 12 and the memory layer 4. For the other description of the insulations 5, the description of the insulations 5 illustrated in FIG. 17 can be referred to as required.

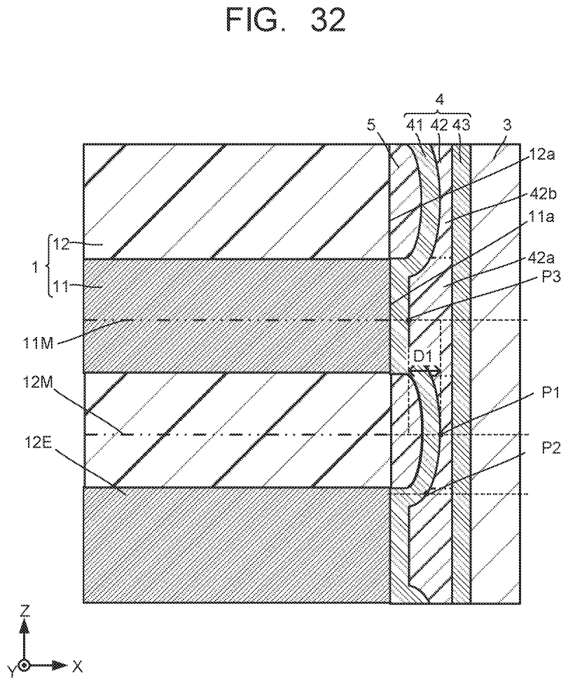

FIG. 32 is an enlarged view illustrating part of FIG. 30. The block insulation film 41 and the charge storage film 42 define an interface therebetween in a cross-section of the NAND string NS, the charge storage film 42 and the tunnel insulation film 43 define an interface therebetween in the cross-section, the tunnel insulation film 43 and the semiconductor layer 3 define therebetween in the cross-section, the cross-section including the conductive layers 11, the insulating layers 12, the semiconductor layer 3, the memory layer 4, and the insulations 5 and being taken along the Z-axis direction. Each of the interfaces have a first point, a second point, and a third point, the first point overlapping with a middle portion 12M in the Z-axis-direction of the insulating layer 12 in the X-axis direction or the Y-axis direction, the second point overlapping with end portions 12E in the Z-axis-direction of the insulating layer 12 in the X-axis direction or the Y-axis direction, and the third point overlapping with a middle portion 11M in the Z-axis-direction of the conductive layers 11. The middle portion 11M are a region whose depth from the upper surface or the lower surface of the conductive layer 11 is half the thickness (Z-axis-direction length) of the conductive layer 11, for instance. The middle portions 12M are each a region whose depth from the upper surface or the lower surface of the insulating layer 12 is half the thickness (Z-axis-direction length) of the insulating layer 12, for instance. The end portions 12E are regions in contact with end portions of the conductive layers 11 in the Z-axis direction. The second points are provided above and under the first point respectively. FIG. 32 illustrates an example where the interface between the block insulation film 41 and the charge storage film 42 has points P1, points P2, and points P3, each point P1 overlapping with the middle portion 12M in the Z-axis-direction of the insulating layers 12, each point P2 overlapping the end portion 12E in the Z-axis-direction of the insulating layers 12, and each point P3 overlapping with the middle portion 11M.

In the interfaces, the second point are closer to the insulating layer 12 than the first points in the X-axis direction or the Y-axis direction. The interfaces each have a round shape or an arch shape bulging toward the semiconductor layer 3. Each of the interface curves from the first point to the second points above and under the first point to protrude toward the semiconductor layer 3. For example, as illustrated in FIG. 32, the interface between the block insulation film 41 and the charge storage film 42, curves from the point P1 to the points P2 above and under the point P1 to protrude toward the semiconductor layer 3.

In each of the interfaces, a distance D1 in the X-axis direction or the Y-axis direction between the second point and the third point is preferably not less than 2 nm nor more than 7 nm. If it is less than 2 nm, it is difficult to reduce electrical interface between the adjacent memory cells MC. If it exceeds 7 nm, an electric field concentrates on the middle portions 11M when a voltage is applied at the time of data write to the memory cells MC, which may lower write efficiency.

The insulations 5 each may have a thickness (X-axis-direction or Y-axis-direction length) that decreases from the first point toward the second points of the interfaces. The thickness of the insulations 5 is preferably not less than 2 nm nor more than 7 nm. This indicates that all the regions from the parts where the thickness of the insulations 5 is smallest up to the parts where the thickness is largest may have a thickness of not less than 2 nm nor more than 7 nm.

Each insulation 5 may further contain carbon. The concentration of the carbon in the insulation 5 is preferably not less than 1 at. % nor more than 20 at. %. If it exceeds 20%, the insulation property of the insulation 5 worsen, which may cause leakage between the word lines L or may lower withstand voltage. In the case where the insulations 5 contain carbon, the insulating layers 12 and the insulations 5 can be distinguished by, for example, a difference in the carbon concentration. The carbon concentration in the insulations 5 is preferably higher than the carbon concentration in the insulating layers 12. That is, a region where the carbon concentration is less than 1 at. % can be defined as the insulating layer 12 and a region where the carbon concentration is not less than 1 at. % nor more than 20 at. % can be defined as the insulation 5. Further, the silicon concentration in the insulation 5 may be lower than the silicon concentration in the insulating layer 12. The element concentrations of the plurality of layers including the insulations 5 and the insulating layers 12 can be measured in an observation section by, for example, element analysis such as TEM-EDX.

Being lower in relative dielectric constant than silicon oxide, carbon-containing silicon oxide is capable of reducing the fringe capacitance of the memory cells and increasing a coupling ratio of the memory transistors MT, and thus is capable of increasing the trapped electron density of regions, of the charge storage film 42, overlapping with the conductive layers 11 in the X-axis direction or the Y-axis direction at the time of, for example, data write, to reduce electrical interference between the adjacent memory cells MC.

The charge storage film 42 may have a thickness (X-axis-direction or Y-axis-direction length) that increases from the first points toward the second points of the interfaces. The thickness of the regions, of the charge storage film 42, overlapping with the first points is preferably smaller than the insulating pars 5. This makes it possible to reduce deterioration in data retention properties due to the spread of electrons in the charge storage film 42. The thickness of the charge storage film 42 is preferably, for example, not less than 2 nm nor more than 10 nm. If it is less than 2 nm, the charge trapping performance worsens to lower, for example, write characteristics. If it exceeds 10 nm, electrical interference between the adjacent memory cells MC becomes large.

The charge storage film 42 has regions 42a overlapping with the conductive layers 11 in the X-axis direction or the Y-axis direction and regions 42b overlapping with the insulations 5 in the X-axis direction or the Y-axis direction. In FIG. 32, boundaries between the regions 42a and the regions 42b are indicated with two-dot chain lines. The regions 42b preferably have a smaller thickness than the thickness of the regions 42a in the X-axis direction or the Y-axis direction. This makes it possible to reduce deterioration in the data retention properties due to the spread of the electrons in the charge storage film 42. It should be noted that this structure is not restrictive, and by thinning the charge storage film 42, the plurality of the regions 42a may be separated without the regions 42b being formed.

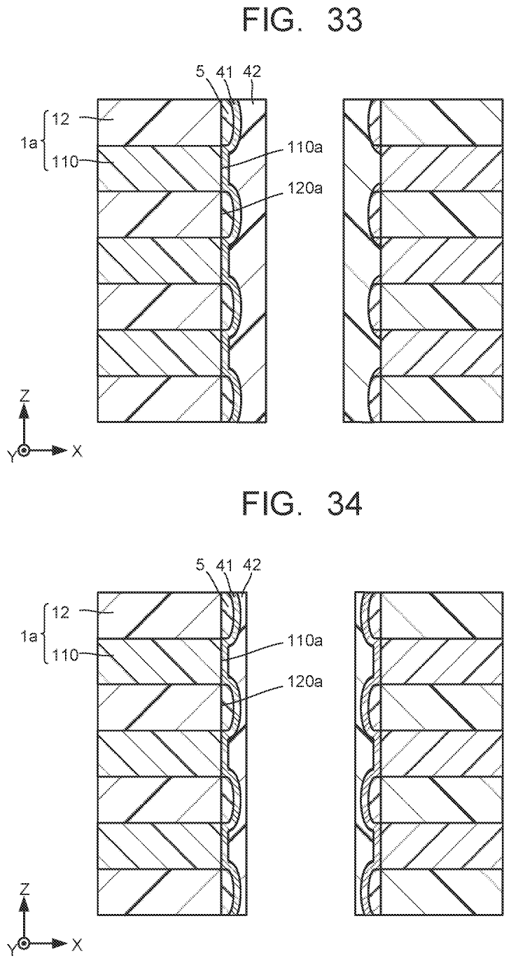

Next, an example of a method of forming the second structure example of the NAND string NS in the method of manufacturing the semiconductor memory device will be described with reference to FIG. 33 to FIG. 36. FIG. 33 to FIG. 36 are explanatory schematic cross-sectional views of the example of the method of forming the second structure example of the NAND string NS and illustrate part of the X-Z cross-section. Here, parts different from those of the example of the method of forming the first structure example will be described, and for the other parts, the description of the example of the method of forming the first structure example can be referred to as required.

First, after up to the block insulation film 41 is formed by the process illustrated in FIG. 20 to FIG. 25 as in the first structure example, the charge storage film 42 is formed on the surface of the block insulation film 41 as illustrated in FIG. 33. The charge storage film 42 can be formed using, for example, CVD or ALD. The charge storage film 42 is preferably thicker than the insulations 5.

Next, as illustrated in FIG. 34, the charge storage film 42 is partly removed in the thickness direction (the X-axis direction or the Y-axis direction) to be thinned. The charge storage film 42 can be partly removed using, for example, wet etching or chemical dry etching (CDE).

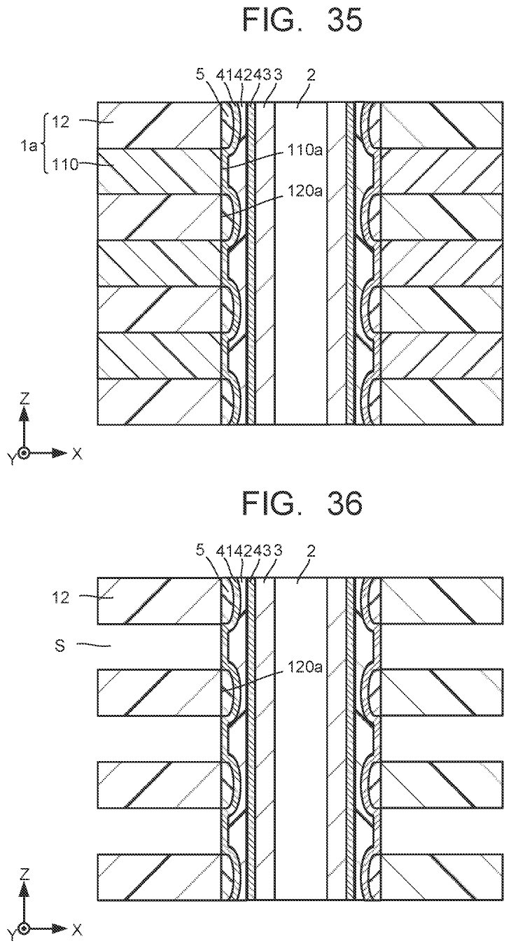

Next, as in the first structure example, as illustrated in FIG. 35, the tunnel insulation film 43 is formed on the surface of the charge storage film 42, the semiconductor layer 3 is formed on the surface of the tunnel insulation film 43, and the insulator 2 is formed on the surface of the semiconductor layer 3. The tunnel insulation film 43, the semiconductor layer 3, and the insulator 2 can be formed using, for example, CVD or ALD.

Next, as in the first structure example, as illustrated in FIG. 36, insulating layers 110 are removed, whereby space S are formed, and thereafter, the conductive layers 11 are formed in the spaces S. Through the above process, the second structure example of the NAND string NS can be formed.

As described above, in the second structure example of the NAND string NS, the thickness of the charge storage film 42 varies in the Z-axis direction, which makes it possible to reduce deterioration in the data retention properties due to the spread of the electrons in the charge storage film 42. Further, increasing the thickness of the charge storage film 42 from the first points toward the second points of the interfaces makes it possible to form the charge storage film 42 with a high quality without increasing an aspect ratio of a memory hole MH, which makes it possible to reduce deterioration in the charge retention properties, for instance. Consequently, operation failures of the memory cells MC can be reduced.

The constituent elements of the second structure example may be appropriately combined with the constituent elements of the first structure example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stack having an insulating layer and a conductive layer, the insulating layer and the conductive layer being stacked alternately in a first direction;
a semiconductor layer provided through the insulating layer and the conductive layer;
a memory layer provided between the stack and the semiconductor layer in a second direction intersecting with the first direction; and
an insulation extending from the insulating layer toward the semiconductor layer in the second direction,
wherein the insulation and the memory layer define an interface therebetween in a cross-section along the first direction, the cross-section including the stack, the semiconductor layer, the memory layer and the insulation, the interface having a first point and a second point, the first point overlapping with a middle portion in the first direction of the insulating layer, the second point overlapping with an end portion in the first direction of the insulating layer,
wherein the second point is closer to the insulating layer in the second direction than the first point is, and
wherein the interface curves from the first point to the second point to protrude toward the semiconductor layer.

2. The device according to claim 1,
wherein the memory layer has:
a block insulation film provided between the conductive layer and the semiconductor layer and between the insulation and the semiconductor layer;
a tunnel insulation film provided between the block insulation film and the semiconductor layer; and
a charge storage film provided between the block insulation film and the tunnel insulation film, and
wherein the charge storage film has:
a first region overlapping with the conductive layer in the second direction; and
a second region overlapping with the insulation in the second direction, and
wherein the second region is smaller in thickness in the second direction than the first region.

3. The device according to claim 1,
wherein the insulation contains silicon, oxygen, and carbon, and
wherein a concentration of the carbon in the insulation is higher than a concentration of carbon in the insulating layer.

4. The device according to claim 3,
wherein the concentration of the carbon in the insulation is not less than 1 at. % nor more than 20 at. %, and
wherein the insulation has a thickness of not less than 0.5 nm nor more than 5 nm in the second direction.

5. The device according to claim 1,
wherein the interface further has a third point overlapping with a middle portion in the first direction of the conductive layer, and
wherein a distance between the first point and the third point in the second direction is not less than 0.5 nm nor more than 5 nm.

6. A semiconductor memory device comprising:
a stack having a first insulating layer, a first conductive layer, a second insulating layer, and a second conductive layer, the first conductive layer being stacked on the first insulating layer in a first direction, the second insulating layer being stacked on the first conductive layer in the first direction, and the second conductive layer being stacked on the second insulating layer in the first direction;
a semiconductor layer provided through the first and second insulating layers and the first and second conductive layers;
a memory layer provided between the stack and the semiconductor layer in a second direction intersecting with the first direction;
a first insulation extending from the first insulating layer toward the semiconductor layer in the second direction; and
a second insulation extending from the second insulating layer toward the semiconductor layer in the second direction,
wherein the first insulation and the memory layer define a first interface therebetween in a cross-section along the first direction, the cross-section including the stack, the semiconductor layer, the memory layer and the first and second insulations, the first interface having a first point and a second point, the first point overlapping with a middle portion in the first direction of the first insulating layer, the second point overlapping with an end portion in the first direction of the first insulating layer,
wherein the second insulation and the memory layer define a second interface therebetween in the cross-section, the second interface having a fourth point and a fifth point, the fourth point overlapping with a middle portion in the first direction of the second insulating layer, the fifth point overlapping with an end portion in the first direction of the second insulating layer,
wherein the second point is closer to the first insulating layer in the second direction than the first point is,
wherein the fifth point is closer to the second insulating layer in the second direction than the fourth point is,
wherein the first interface curves from the first point to the second point to protrude toward the semiconductor layer, and
wherein the second interface curves from the fourth point to the fifth point to protrude toward the semiconductor layer.

7. The device according to claim 6,
wherein the memory layer has:
a block insulation film continuously provided and extends between the first conductive layer and the semiconductor layer, between the first insulation layer and the semiconductor layer, between the second conductive layer and the semiconductor layer, and between the second insulation and the semiconductor layer;
a tunnel insulation film provided between the block insulation film and the semiconductor layer; and
a charge storage film provided between the block insulation film and the tunnel insulation film, and
wherein the charge storage film has:
a first region overlapping with the first conductive layer in the second direction;
a second region overlapping with the first insulation in the second direction;
a third region overlapping with the second conductive layer in the second direction; and
a fourth region overlapping with the second insulation in the second direction,
wherein the second region is smaller in thickness in the second direction than the first region, and
wherein the fourth region is smaller in thickness in the second direction than the third region.

8. The device according to claim 6,
wherein each of the first and second insulations contains silicon, oxygen, and carbon, and
wherein a concentration of the carbon in the first insulation is higher than a concentration of carbon in the first insulating layer, and
wherein a concentration of the carbon in second first insulation is higher than a concentration of carbon in the second insulating layer.

9. The device according to claim 8,
wherein the concentration of the carbon in the first insulation is not less than 1 at. % nor more than 20 at. %,
wherein the concentration of the carbon in the second insulation is not less than 1 at. % nor more than 20 at. %,
wherein the first insulation has a thickness of not less than 0.5 nm nor more than 5 nm in the second direction, and
wherein the second insulation has a thickness of not less than 0.5 nm nor more than 5 nm in the second direction.

10. The device according to claim 6,
wherein the first interface further has a third point overlapping with a middle portion in the first direction of the first conductive layer,
wherein the second interface further has a sixth point overlapping with a middle portion in the first direction of the second conductive layer,
wherein a distance between the first point and the third point in the second direction is not less than 0.5 nm nor more than 5 nm, and
wherein a distance between the fourth point and the sixth point in the second direction is not less than 0.5 nm nor more than 5 nm.

11. The device according to claim 6,
wherein each of the first and second insulating layers contains silicon and oxygen.

12. The device according to claim 6,
wherein the first insulation do not be in contact with each of the first and the second conductive layers, and
wherein the second insulation do not be in contact with each of the first and the second conductive layers.

13. The device according to claim 6,
wherein the memory layer does not be in contact with each of the first and second insulating layers.

14. The device according to claim 7,
wherein the block insulation film is in contact with each of the first and second insulations.

15. The device according to claim 7,
wherein the block insulation film is in contact with each of the first and second conductive layers.

16. A method of manufacturing a semiconductor memory device, the method comprising:
alternately stacking a first layer and a second layer in a first direction to form a stack;
partly removing the stack along the first direction to form an opening through the stack in the first direction, a first surface provided on the first layer and facing on the opening, and a second surface provided on the second layer and facing on the opening;
forming a protective film onto the first surface;
forming an insulation extending in a second direction intersecting with the first direction from the second surface toward the opening;
removing the protective film;
forming a memory layer onto the first surface and the insulation;
forming a semiconductor layer onto an opposite side of the memory layer from the first surface and onto an opposite side of the memory layer from the insulation in the second direction; and
removing the first layer to form a space and forming a third layer in the space.

17. The method according to claim 16,
wherein the insulation and the memory layer define an interface therebetween in a cross-section along the first direction, the cross-section including the stack, the semiconductor layer, the memory layer and the insulation, the interface having a first point and a second point, the first point overlapping with a middle portion in the first direction of the second layer, the second point overlapping with an end portion in the first direction of the second layer,
wherein the second point is closer to the second layer in the second direction than the first point, and
wherein the interface curves from the first point to the second point to protrude toward the semiconductor layer.

18. The method according to claim 16,
wherein the memory layer has:
a block insulation film provided between the first surface and the semiconductor layer and between the insulation and the semiconductor layer;
a tunnel insulation film provided between the block insulation film and the semiconductor layer; and
a charge storage film provided between the block insulation film and the tunnel insulation film, and
wherein the charge storage film has:
a first region overlapping with the third layer in the second direction; and
a second region overlapping with the insulation in the second direction, and
wherein the second region is smaller in thickness in the second direction than the first region.

19. The method according to claim 16,
wherein the first layer contains silicon and nitrogen,
wherein the second layer contains silicon and oxygen,
wherein the insulation contains silicon, oxygen, and carbon, and
wherein a concentration of the carbon in the insulation is higher than a concentration of carbon in the first layer.

20. The method according to claim 19,
wherein the concentration of the carbon in the insulation is not less than 1 at. % nor more than 20 at. %, and
wherein the insulation has a thickness of not less than 2 nm nor more than 7 nm in the second direction.
